(19) United States
(12) Patent Application Publication
(10) Pub. No.: US 2026/0211189 A1
(43) Pub. Date: Jul. 23, 2026

(54) SINGLE-PHOTON SOURCE DEVICE

(71) Applicant: Korea Research Institute of Standards and Science, Daejeon (KR)

(72) Inventors: Kee Suk HONG, Daejeon (KR); Hee Jin LIM, Daejeon (KR); In Ho BAE, Daejeon (KR)

(21) Appl. No.: 19/448,353

(22) Filed: Jan. 14, 2026

(30) Foreign Application Priority Data
Jan. 15, 2025 (KR) 10-2025-0006054

(51) Int. Cl. G02B 6/34

(52) U.S. Cl. CPC G02B 6/34

(57) ABSTRACT

Disclosed is a single-photon source device according to embodiments, which includes a microscope part including a stage that is three-dimensionally movable, a wafer disposed on the stage, a laser part configured to emit light to the wafer, and a single-mode fiber (SMF) input/output module configured to emit an optical signal reflected by the wafer to an outside, wherein the wafer includes a substrate and a wafer layer disposed on the substrate, and the wafer layer has a surface on which the light is incident and which includes a plurality of circular patterns forming concentric circles.

### CROSS-REFERENCE TO RELATED APPLICATION

This application claims priority to and the benefit of Korean Patent Application No. 10-2025-0006054, filed on Jan. 1, 2025, the disclosure of which is incorporated herein by reference in its entirety.

### BACKGROUND

### 1. Field of the Invention

Embodiments relate to a single-photon source device.

### 2. Discussion of Related Art

Quantum information and communication technology is a core of the future information and communication technology and has the advantages of high security and fast processing speed. One fundamental factor of the quantum information and communication technology is a single-photon source. A single-photon source is a device capable of generating photons, which are quantum units of electromagnetic waves, one by one and transmitting the photons, and performs an essential role in various fields such as quantum cryptography communication, quantum computing, and quantum metrology. However, most of the currently commercialized single-photon sources operate in cryogenic environments or are pseudo single-photon sources and have problems of security and reliability.

Single-photon sources perform roles for maximizing security in information and communication systems. In particular, in quantum cryptography communication, a single-photon provides security by utilizing no-cloning theorem, and when a multi-photon state occurs, a problem may occur in security. Light sources used in currently commercialized quantum cryptography systems are pseudo single-photon sources that attenuate output power of a laser to generate a state close to a single-photon on average. However, these pseudo single-photon sources have the disadvantage of being vulnerable in security due to the high probability of multi-photon generation.

A deterministic single-photon source is needed to solve this problem. The deterministic single-photon source may deterministically generate a single-photon in the specific time and space and thus provide the high security and reliability in the quantum cryptography communication and other quantum technologies.

The single-photon source is broadly divided into two types of sources according to a generation method. The first is a heralded single-photon source uses a method of generating a pair of photons using a nonlinear optical phenomenon, and then one of the pair of photons heralds occurrence probability of the other photon. The second is a single-emitter single-photon source, which controls a specific single atom, a quantum dot, or defect structure to generate only one photon.

Conventional single-photon source systems have a very large scale that can be implemented in a laboratory and are formed using various types of devices. Therefore, the conventional single-photon source systems are not suitable for light sources for quantum communication or other systems. In addition, it has the disadvantage that a light source is very difficult to find and stabilization is difficult to achieve. In addition, there is a problem that brightness of the light source is degraded and thus extraction efficiency of the single-photon source is insufficient.

### SUMMARY OF THE INVENTION

Embodiments provide a single-photon source device having increased brightness of a single-photon source.

In addition, embodiments provide a single-photon source device with improved extraction of a single-photon.

In addition, embodiments provide a single-photon source device capable of continuously measuring a light emission intensity.

In addition, embodiments provide a single-photon source device capable of operating at room temperature and being miniaturized.

In addition, embodiments provide a single-photon source device with high precision and high stability of photon generation.

Problems to be solved in the embodiments are not limited to the above-described problems, and objects and effects which may be determined from the solutions and the embodiments of the problems that are described below are also included.

The single-photon source device according to embodiments includes a microscope part including a stage that is three-dimensionally movable, a wafer disposed on the stage, a laser part configured to emit light to the wafer, and a single-mode fiber (SMF) input/output module configured to emit an optical signal reflected by the wafer to an outside, wherein the wafer includes a substrate and a wafer layer disposed on the substrate, and the wafer layer has a surface on which the light is incident and which includes a plurality of circular patterns forming concentric circles. The plurality of circular patterns may be etched to a predetermined depth from the surface of the wafer layer on which the light is incident in a direction in which the light is incident.

The plurality of circular patterns may include a first circular pattern having a first diameter and a second circular pattern having a second diameter different from the first diameter.

The first diameter may be smaller than the second diameter, and the wafer layer may include a protruding structure disposed on an inner side of the first circular pattern.

A diameter of the protruding structure may be greater than a width of the first circular pattern in a first direction, and the first direction may be a direction perpendicular to the direction in which the light is incident on the wafer layer.

The plurality of circular patterns may further include a third circular pattern to a tenth circular pattern disposed outside the second circular pattern.

The wafer layer may be etched to 0.6 μm to 1.2 μm in a direction perpendicular to the surface on which the light is incident.

A surface of the etched wafer layer may be spaced apart from the substrate by 0.09 μm to 0.11 μm.

The substrate may be a sapphire substrate, and the wafer layer may be a GaN layer.

The plurality of circular patterns may be a circular Bragg grating (CBG).

A thickness of the intermediate layer may range from 1500 nm to 1540 nm.

A difference between the first diameter and the second diameter may range from 320 nm to 420 nm.

A height of each of the first circular pattern and the second circular pattern may range from 240 nm to 260 nm.

### BRIEF DESCRIPTION OF THE DRAWINGS

The above and other objects, features and advantages of the present invention will become more apparent to those of ordinary skill in the art by describing exemplary embodiments thereof in detail with reference to the accompanying drawings, in which:

FIG. 1 is a block diagram of a single-photon source device according to an embodiment, and FIG. 2 is a schematic diagram of the single-photon source device according to the embodiment;

FIG. 3 is a schematic diagram of a wafer of a conventional single-photon source device;

FIGS. 4 and 5 are schematic diagrams of a wafer of the single-photon source device according to the embodiment;

FIG. 6 shows images of a wafer of the single-photon source device according to the embodiment;

FIG. 7 is a reference diagram illustrating an operation of etching the wafer of the single-photon source device according to the embodiment;

FIG. 8 shows images illustrating a state of the etched wafer of the single-photon source device according to the embodiment;

FIGS. 9A to 9C are images of the single-photon source device according to the embodiment; and

FIGS. 10A to 10D, 11, 12, 13A to 13D and 14A to 14D are graphs showing effects of the single-photon source device according to the embodiment.

### DETAILED DESCRIPTION OF EXEMPLARY EMBODIMENTS

Hereinafter, exemplary embodiments of the present invention will be described in detail with reference to the accompanying drawings.

However, the technical idea of the present invention is not limited to some embodiments to be described but may be implemented in various different forms, and, within the scope of the technical idea of the present invention, one or more among components in the embodiments may be used by being selectively combined and substituted.

Further, unless specifically defined and described, terms used in the embodiments of the present invention (including technical and scientific terms) may be construed as meanings which are generally understood by those skilled in the art to which the present invention pertains, and generally used terms such as terms defined in the dictionary may be interpreted in consideration of the contextual meaning of the related art.

In addition, terms used in the embodiments of the present invention are intended to describe the embodiments and are not intended to limit the present invention.

In the present specification, the singular forms may include the plural forms unless the context clearly dictates otherwise, and when described as “at least one (or one or more) among A, B, and (or) C,” it may include one or more among all combinations in which A, B, and C can be combined.

In addition, in describing components of embodiments of the present invention, the terms first, second, A, B, (a), (b), and the like can be used.

These terms are intended to distinguish one component from other components, but the nature and the order or sequence of the components is not limited by those terms.

In addition, when a component is described as being “linked,” “coupled,” or “connected” to another component, the component is not only directly linked, coupled, or connected to another component, but also “linked,” “coupled,” or “connected” to another component with still another component disposed between the component and another component.

In addition, when a component is described as being formed or disposed “on (above) or under (below)” of another component, the term “on (above) or under (below)” includes not only when two components are in direct contact with each other, but also when one or more of other components are formed or disposed between the two components. Further, when a component is described as being “on (above) or below (under),” the description may include the meanings of an upward direction and a downward direction based on one component.

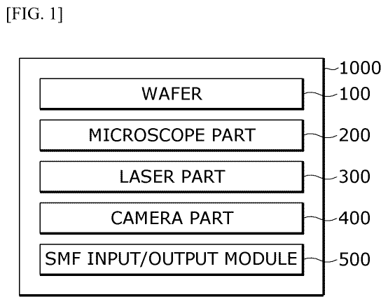

FIG. 1 is a block diagram of a single-photon source device according to an embodiment, and FIG. 2 is a schematic diagram of the single-photon source device according to the embodiment.

Referring to FIGS. 1 and 2, a single-photon source device 1000 according to an embodiment may include a wafer 100, a microscope part 200, a laser part 300, a camera part 400, and a single-mode fiber (SMF) input/output module 500.

The wafer 100 may receive light and reflect the received light as an optical signal. The wafer 100 may receive light and generate a single-photon. The wafer 100 may be a thin substrate. The wafer 100 may include a substrate and a wafer layer. For example, the wafer 100 may be in the form in which a GaN wafer are stacked on a sapphire substrate. The wafer 100 according to the embodiment may have an effect of allowing the single-photon source to operate at room temperature using GaN. For example, the wafer 100 is a p-type semiconductor and may include a GaN thin film doped with magnesium (Mg). In addition, for example, a diameter of the wafer 100 is 2 inches, a thickness thereof is 0.43 mm, and a thickness of the GaN thin film is 4.5 μm so as to form an important active layer of a photoelectron and high-power electronic device. A process of the wafer 100 may be a photolithography (optical lithography) process for a GaN wafer grown on a sapphire substrate. A photoresist (PR) may be uniformly applied onto a wafer surface with a thickness of 1.5 μm, and then a process of transferring a mask pattern to the wafer through ultraviolet (UV) exposure is performed, and the transferred pattern may be selectively etched or deposited through a subsequent process.

The wafer 100 may be disposed on a stage 210 of the microscope part 200. The wafer 100 may be disposed on the stage 210 to be moved three-dimensionally. The wafer 100 may be disposed on the stage 210 to be finely moved three-dimensionally and thus moved very finely and precisely. The wafer 100 may be moved on the stage 210 to receive light emitted from the laser part 300.

The microscope part 200 may include the stage 210, an objective lens 220, and a first mirror M1. The stage 210 on which the wafer 100 is disposed may fix the wafer 100. The stage 210 may perform a three-dimensional fine movement by moving in an X-axis, Y-axis, and Z-axis directions. Therefore, the stage 210 may finely move a position of the wafer 100 three-dimensionally. The objective lens 220 may change a path of the light to concentrate the light on the wafer 100 of the stage 210. In addition, the objective lens 220 may transmit an optical signal emitted from the wafer 100 to the outside. The objective lens 220 may be disposed between the stage 210 and the first mirror M1. The first mirror M1 may reflect light and change a path of the light to direct the light toward the objective lens 220. In addition, the first mirror M1 may change the path of the light passing through the objective lens 220 to direct the light toward a second splitter 440. Here, a Z-axis direction may correspond to a direction in which light is incident on the wafer 100, and an X-axis direction and a Y-axis direction may correspond to a first direction and a second direction, respectively.

The laser part 300 may include a light source 310, a first filter 320, a second mirror M2, a second filter 330, a third mirror M3, and a fourth mirror M4. The light source 310 may output and radiate light. The light source 310 may be a pump light source that emits laser-pump light. The first filter 320 and the second filter 330 may filter a portion of the light emitted from the laser part 300. The first filter 320 may include a variable neutral density (ND) filter. In addition, the second filter 330 may include a band pass filter. The second mirror M2 may be disposed between the first filter 320 and the second filter 330. The second mirror M2 may reflect the light passing through the first filter 320 toward the second filter 330. The third mirror M3 may be disposed between the second filter 330 and the fourth mirror M4. The third mirror M3 may reflect the light passing through the second filter 330 toward the fourth mirror M4. The fourth mirror M4 may be disposed between the third mirror M3 and the second splitter 440. The fourth mirror M4 may change an optical path by selecting a portion of the light according to a wavelength of the light. The fourth mirror M4 may include a dichroic mirror. The fourth mirror M4 may transmit a portion of the light and reflect the remaining light. The light passing through the fourth mirror M4 may be directed toward the second splitter 440. In addition, the fourth mirror M4 may reflect the light passing through the second splitter 440 toward a third filter 520 of the SMF input/output module 500.

The camera part 400 may include a camera 410, a first splitter 420, a white light source 430, and the second splitter 440. The camera 410 may receive light reflected by the wafer 100 and acquire an image of the wafer 100. In addition, the camera 410 may receive the light radiated from the light source 310. The camera 410 may include a charge coupled device (CCD) camera. The first splitter 420 may transmit a portion of the light and reflect the remaining light. The first splitter 420 may pass the light reflected by the second splitter 440 to allow the light to reach the camera 410. The white light source 430 may emit white light. The white light emitted from the white light source 430 may reach the microscope part 200 through the splitter. The second splitter 440 may transmit a portion of the light and reflect the remaining light. The second splitter 440 may reflect a portion of the light emitted from the laser part 300 and transmit the remaining light. In addition, the second splitter 440 may reflect a portion of the light reflected by the wafer 100 and transmit the remaining light. The second splitter 440 may be disposed between the first mirror M1 and the fourth mirror M4. The single-photon source device 1000 may include the camera part 400 and, thus, facilitate optical alignment. The single-photon source device 1000 may emit light different from that of the light source 310 through the white light source 430, thereby performing optical alignment easily. In addition, a light emission intensity of the wafer may be continuously measured through the camera part.

The SMF input/output module 500 may include an SMF 510, the third filter 520, a fourth filter 530, a fifth mirror M5, a sixth mirror M6, and a seventh mirror M7. The SMF 510 may refer to a single mode optical fiber. The SMF 510 may transmit and receive an optical signal. The SMF 510 may emit the optical signal reflected by the wafer 100 to the outside. The optical signal may be emitted to the outside through an end 511 of the SMF 510. The third filter 520 may transmit the light signal reflected by the fourth mirror M4. The third filter 520 may include a long pass filter. The fifth mirror M5, the sixth mirror M6, and the seventh mirror M7 may sequentially reflect the light passing through the third filter 520 to allow the light to reach the fourth filter 530. The fifth mirror M5, the sixth mirror M6, and the seventh mirror M7 may be disposed between the third filter 520 and the fourth filter 530. The fourth filter 530 may transmit the optical signal to allow the optical signal to reach the SMF 510. The fourth filter 530 may include a long-pass filter.

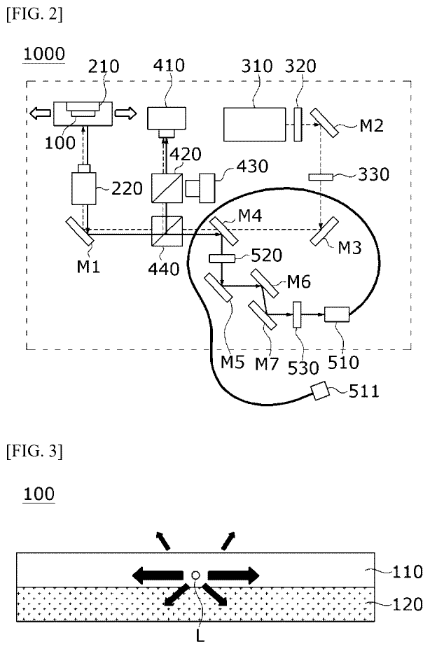

FIG. 3 is a schematic diagram of a wafer of a conventional single-photon source device.

Referring to FIG. 3, the wafer 100 of the conventional single-photon source device may include a wafer layer 110 and a substrate 120. The wafer layer 110 may be disposed on the substrate 120. The wafer 100 may include a form in which the wafer layer 110 is stacked on the substrate 120. When the light is incident on the wafer layer 110, the light is reflected to generate a single-photon. When the light is incident on the wafer layer 110, a single-photon may be generated at a predetermined point L. In the case of the conventional single-photon source device, there is a problem that the generated single-photon is emitted in a direction other than a surface direction of the wafer layer 110, and thus brightness of the single-photon source is degraded.

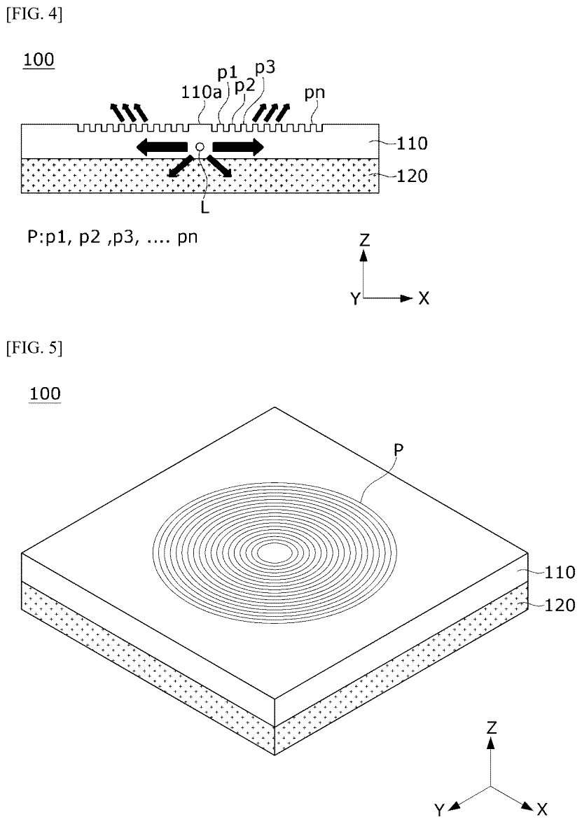

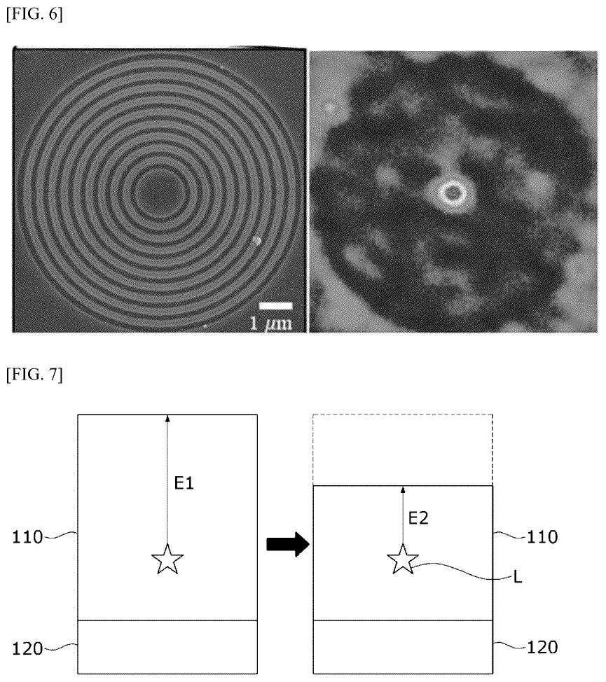

FIGS. 4 and 5 are schematic diagrams of a wafer of the single-photon source device according to the embodiment, and FIG. 6 shows images of a wafter of the single-photon source device according to the embodiment. FIG. 6A may be a scanning electron microscope (SEM) image of the wafer, and FIG. 6B may be a fluorescence scan image of the wafer.

Referring to FIGS. 4 to 6, the wafer 100 of the single-photon source device may include a wafer layer 110 and a substrate 120, and the wafer layer 110 may include a plurality of circular patterns P.

The wafer layer 110 may be disposed on the substrate 120. The wafer 100 may include a form in which the wafer layer 110 is stacked on the substrate 120. The substrate 120 may include a sapphire substrate. The wafer layer 110 may include a GaN layer. The wafer layer 110 may be made of 100% GaN. The wafer 100 may include the GaN layer, thereby enabling the single-photon source device to operate at room temperature. Each of the substrate 120 and the wafer layer 110 may have a predetermined thickness in the direction in which the light is incident. When the light is incident on the wafer layer 110, the light is reflected to generate a single-photon. The single-photon may be generated at a specific point L inside the wafer layer 110. The wafer layer 110 may have predetermined widths in the first direction and the second direction. The first direction and the second direction may be directions perpendicular to the direction in which the light is incident on the wafer 100. In addition, the second direction may be a direction perpendicular to the first direction. That is, the first direction and the second direction may be directions perpendicular to a surface of the wafer layer 110 on which the light is incident. For example, the wafer layer 110 may have widths ranging from 4.9 inches to 5.1 inches in the first direction and the second direction.

The wafer layer 110 may include the plurality of circular patterns P. The plurality of circular patterns P may be disposed on the surface of the wafer layer 110 on which the light is incident. The plurality of circular patterns P may form concentric circles on the surface of the wafer layer 110 on which the light is incident. Each circular pattern included in the plurality of circular patterns P may have a predetermined diameter. In addition, each circular pattern may have a predetermined height and a predetermined width. A height of the circular pattern may refer to a height in the direction in which the light is incident on the wafer layer 110. In addition, a width of the circular pattern may refer to a shortest distance between the outer and inner surfaces of the circular pattern. The plurality of circular patterns P may form concentric circles when viewed from the top. That is, the centers of plurality of circular patterns P may be the same. The plurality of circular patterns P may be disposed to be spaced a predetermined distance from each other. The plurality of circular patterns may include a circular Bragg grating (CBG).

The plurality of circular patterns P may be etched to a predetermined depth from the surface of the wafer layer 110, on which the light is incident, in a direction in which the light is incident. That is, the plurality of circular patterns P may be formed by a method of etching to a predetermined depth in a direction perpendicular to the surface of wafer layer 110. The plurality of circular patterns P may each have a predetermined height in the direction perpendicular to the surface of the wafer layer 110. Heights of the plurality of circular patterns P may be the same. The plurality of circular patterns may each have a predetermined grating period. The grating period of the circular pattern may refer to a difference between diameters of two adjacent circular patterns.

The plurality of circular patterns P may include a first circular pattern p1 having a first diameter and a second circular pattern p2 having a second diameter different from the first diameter. The first circular pattern p1 may be a pattern disposed at the innermost side among the plurality of circular patterns P. In addition, the second circular pattern p2 may be a pattern disposed adjacent to the first circular pattern p1. The first circular pattern p1 may be a pattern having the smallest size. The first diameter of the first circular pattern p1 may be smaller than the second diameter of the second circular pattern p2.

The wafer layer 110 may include a protruding structure 110a disposed on an inner side of the first circular pattern p1. The protruding structure 110a may be disposed inside the first circular pattern p1. The protruding structure 110a may have a predetermined height in a direction perpendicular to the surface of the wafer layer 110. The protruding structure 110a may include a cylindrical shape. The height of the protruding structure 110a may be equal to the height of each of the plurality of circular patterns P. A diameter of the protruding structure 110a may be smaller than the first diameter of the first circular pattern p1. The protruding structure 110a may be spaced a predetermined distance from the first circular pattern p1. In addition, the diameter of the protruding structure 110a may be greater than a width in the first direction of the first circular pattern p1. The diameter of the protruding structure 110a may range from 1.45 μm to 1.55 μm. For example, the diameter of protruding structure 110a may be 1.52 μm.

The plurality of circular patterns P may include a predetermined number of circular patterns. The plurality of circular patterns P may include n circular patterns p1, p2, p3, . . . , and pn. The n circular patterns p1, p2, p3, . . . , and pn may be disposed sequentially from the inner side of the circular pattern. The plurality of circular patterns P may include a first circular pattern to an n^{th} circular pattern p1, p2, p3, . . . and pn. The n^{th} circular pattern pn may be a pattern disposed at the outermost side among the first circular pattern to the n^{th} circular pattern p1, p2, p3, . . . , and pn. That is, a diameter of the first circular pattern p1 may have the smallest diameter among those of the n circular patterns p1, p2, p3, . . . , and pn, and a diameter of the n^{th} circular pattern pn may have the largest diameter among those of the n circular patterns p1, p2, p3, . . . , and pn. The plurality of circular patterns P may include ten circular patterns. The plurality of circular patterns P may include a first circular pattern to a tenth circular pattern p1, p2, . . . , and p10. The wafer of the single-photon source device includes the plurality of circular patterns, and thus the light can be prevented from being transmitted inside the wafer layer, and the light can be emitted outside the wafer. Accordingly, brightness of the single-photon source may be improved. Referring to FIG. 6B, it can be seen that a distinct light emission intensity was shown in a central portion of the wafer layer.

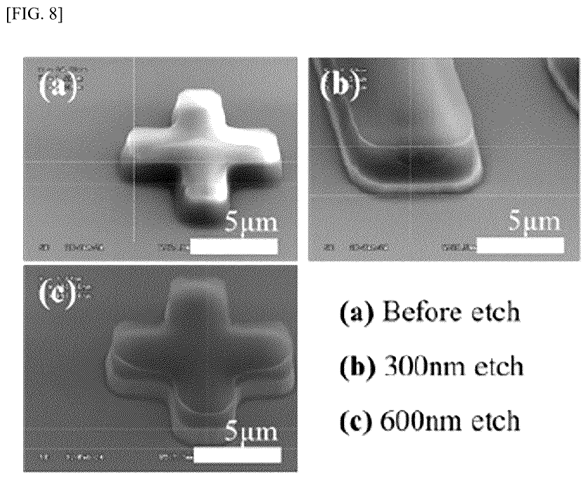

FIG. 7 is a reference diagram illustrating an operation of etching the wafer of the single-photon source device according to the embodiment, and FIG. 8 shows images illustrating a state of the etched wafer of the single-photon source device according to the embodiment.

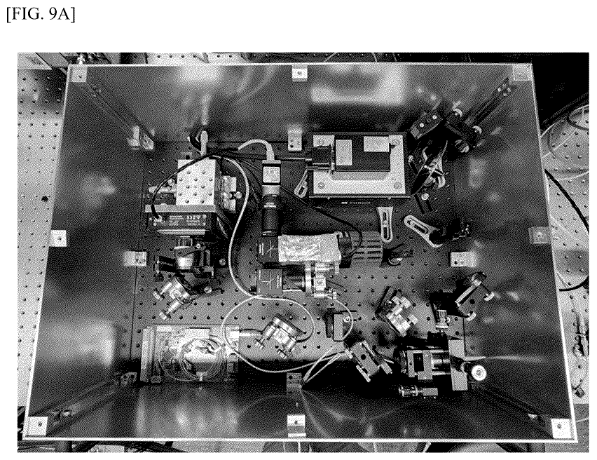

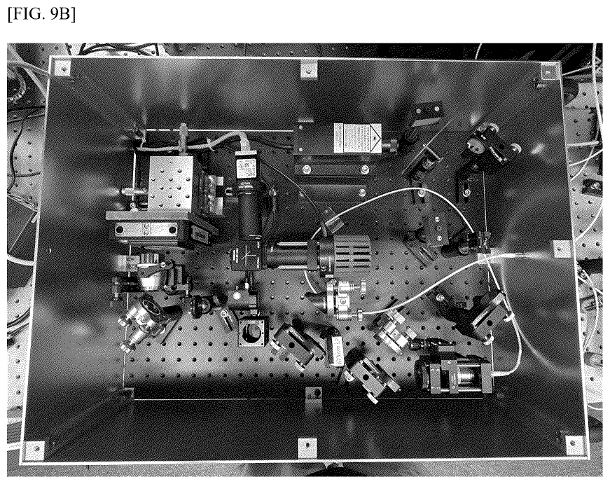

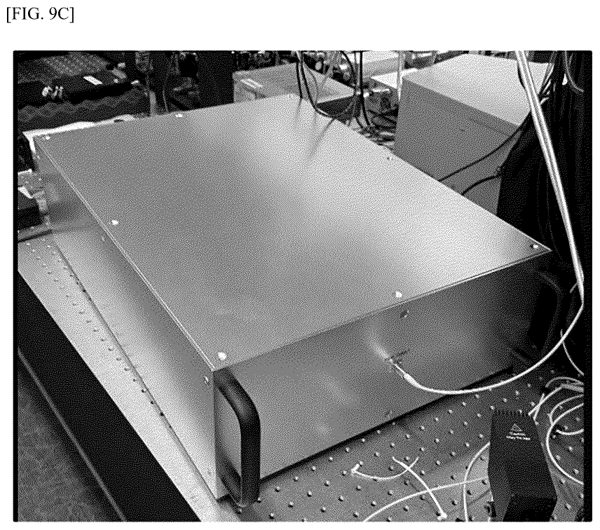

Referring to FIGS. 8 and 9, the wafer layer 110 of the wafer 100 of the single-photon source device may be etched to have a predetermined height. The wafer layer 110 may be etched to have a predetermined height in the direction in which light is incident, i.e., in a direction perpendicular to the surface of the wafer 100. FIG. 8A shows a state of the wafer layer before etching, and FIG. 8B shows a state of the wafer layer after etching. For example, a distance of 1.3 μm from a surface of the wafer layer 110 to a point L at which a single-photon is generated before the etching may be reduced to a distance of 0.7 μm from the surface of the wafer layer 110 to the point L at which the single-photon is generated after the etching. For example, a height at which the wafer layer 110 is etched may range from 0.6 μm to 1.2 μm. The wafer layer 110 is etched so that the surface of the wafer of the single-photon source device may be etched, and thus brightness of the single-photon source can be increased. Etching of the wafer layer 110 may be performed using a dry etching process in which Cl₂ and Ar gases are used through electron beam lithography.

FIGS. 9A to 9C are images of the single-photon source device according to the embodiment.

Referring to FIGS. 9A to 9C, the single-photon source device may be formed as a single device integrated into a 19-inch standard rack metal case. For example, a bottom size of the single-photon source device may be 450 mm* 600 mm or small, and a height thereof may be 186 mm (4U) or small. In addition, a weight of the single-photon source device may be 10 kg or less, the single-photon source device may be capable of performing an air-cooling room temperature operation and may use a single-phase AC power supply with a voltage of 220 V and a frequency of 60 Hz and have power consumption of 500 W or less. The single-photon source device is portable and is installed easily. In addition, the single-photon source device may implement a plug-and-play operation method and, thus, require no preparation work or setup before a power switch operation. Accordingly, despite repeated power-off and power-on, performance can be maintained and reproducibility can be improved. In addition, the single-photon source device can maintain performance at a temperature ranging from 10° C. to 40° C. and humidity ranging from 30% to 65% R.H. or less, thereby improving environmental stability. In addition, the single-photon source device can maintain performance even in daily vehicle driving environments to maintain stability against a vibration and can maintain the performance even after a long-term operation for 100 hours or more, thereby maintaining long-term stability.

In the single-photon source device according to the embodiment, a center wavelength may range from 700 nm to 800 nm and a spectral width (full width half maximum (FWHM)) may be 5 nm or less. A photon flux output through a single-mode optical fiber may be 5*105 s−1 (500 kcps) or more. In addition, single-photon purity of the single-photon source device may be g(2)(0)<0.5, and photon flux output power stability thereof may be 5% or less.

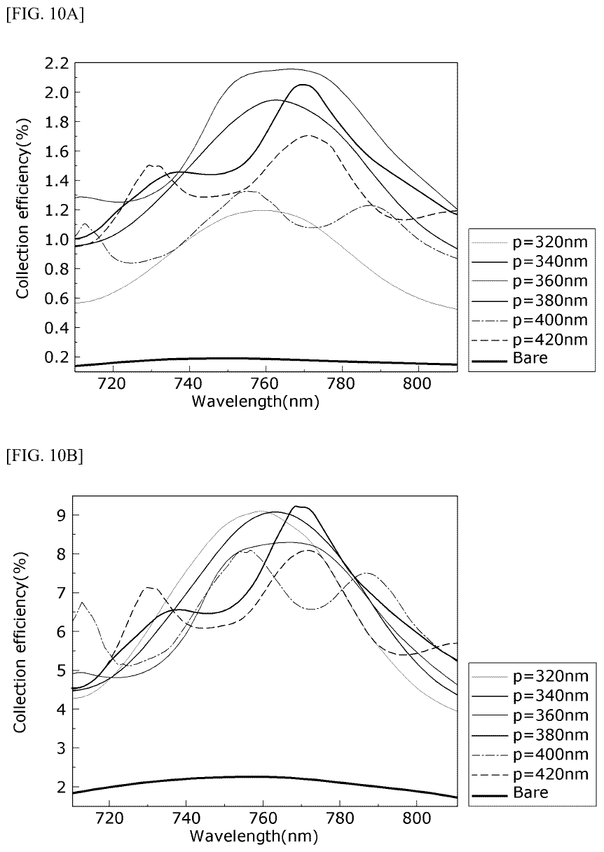

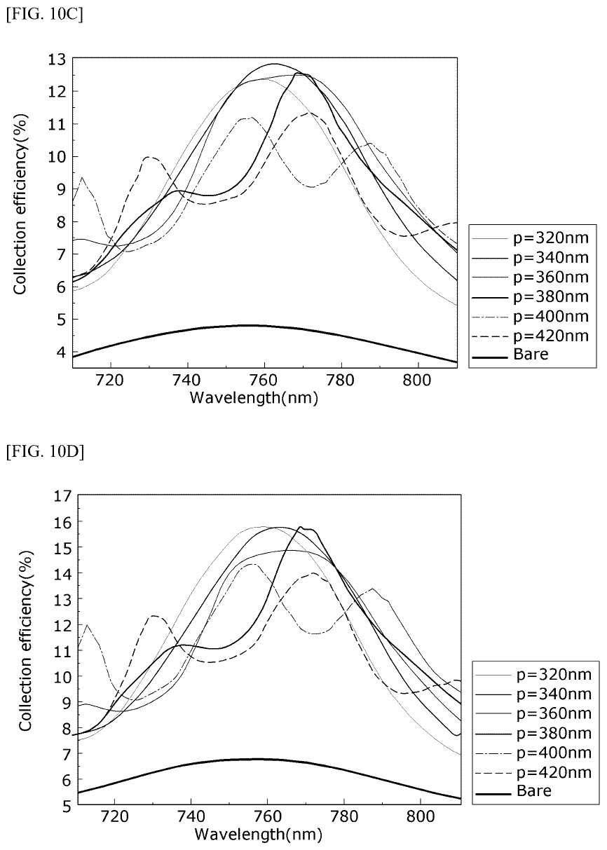

FIGS. 10A to 10D, 11, 12, 13A to 13D and 14A to 14D are graphs showing effects of the single-photon source device according to the embodiment.

FIGS. 10A to 10D show graphs showing collection efficiencies (%) of the single-photon according to wavelengths of light. The case in which grating periods of the circular patterns are 320 nm, 340 nm, 360 nm, 380 nm, 400 nm, and 420 nm, and the case in which the circular patterns are not included are shown. A wavelength spectrum of the light may range from 710 nm to 810 nm. FIG. 10A shows collection efficiency in the case in which a numerical aperture (NA) is 0.14 at a specified angle of 8.05°. FIG. 10B shows collection efficiency in the case in which an NA is 0.5 at a specified angle of 30°. FIG. 10C shows collection efficiency in the case in which an NA is 0.77 at a specified angle of 50°. FIG. 10D shows collection efficiency in the case in which an NA is 0.95 at a specified angle of 72°. The specified angle may refer to an angle based on an optical axis passing through the center of the protruding structure. When the grating period of the circular pattern is 380 nm, the collection efficiency may be improved about 11 times at an angle of 8.05° and about 2 times at 72° compared to the case without including the circular patterns. Consequently, an extraction rate of a single-photon may be effectively improved by arranging the circular patterns on the wafer of the single-photon source device.

FIG. 11 shows the number of photons (count per second (CPS)) measured as a function of power (mW) of the pump light source. As the NA increases, the CPS may be improved. When an objective lens with an NA of 0.95 is used, the CPS may be improved about 1.4 times compared to when the circular patterns are not included. In addition, when an objective lens with an NA of 0.7 is used, the CPS may be improved about 2 times compared to when the circular patterns are not included.

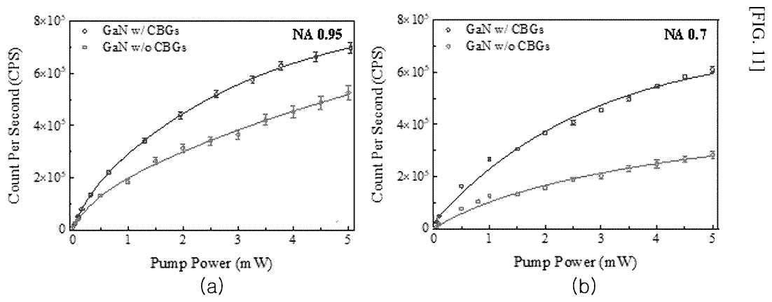

FIG. 12 shows light source purity g²(0) according to a time delay. FIG. 12C shows the case in which an NA is 0.95 and the circular patterns are not included, FIG. 12D shows the case in which an NA is 0.95 and the circular patterns are included, FIG. 12E shows the case in which an NA is 0.7 and the circular pattern are not included, and FIG. 12F shows the case in which an NA is 0.7 and the circular patterns are included. When the circular patterns are included, a narrower and deeper curve shape exhibits compared to when the circular patterns are not included, and thus it can be seen that the circular patterns effectively improve a single-photon collection.

FIGS. 11 and 12 show that a circular Bragg grating is formed and thus the single-photon source emits light with forward directivity. When objective lenses with different NAs are used, a single-photon source with a circular Bragg grating exhibits almost no change in brightness, whereas when the circular Bragg grating is not present, the change in brightness is relatively large. In addition, the purity of the light source exhibits a significant difference according to the presence or absence of the circular Bragg grating.

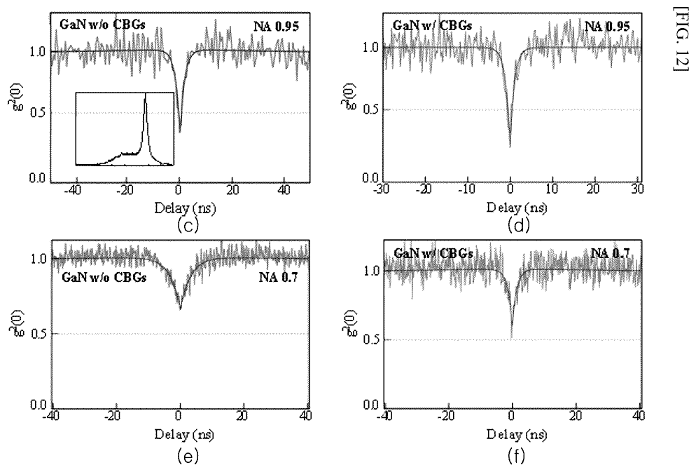

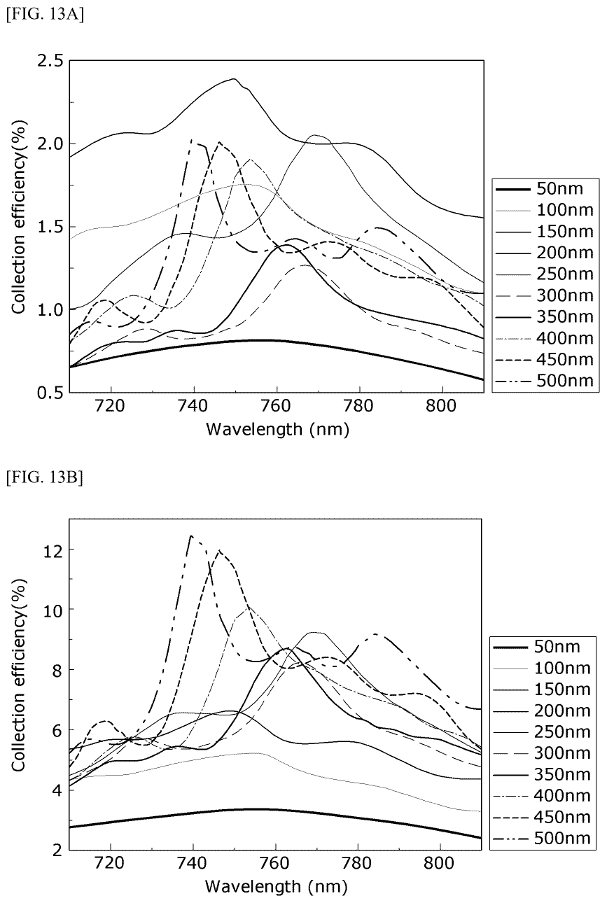

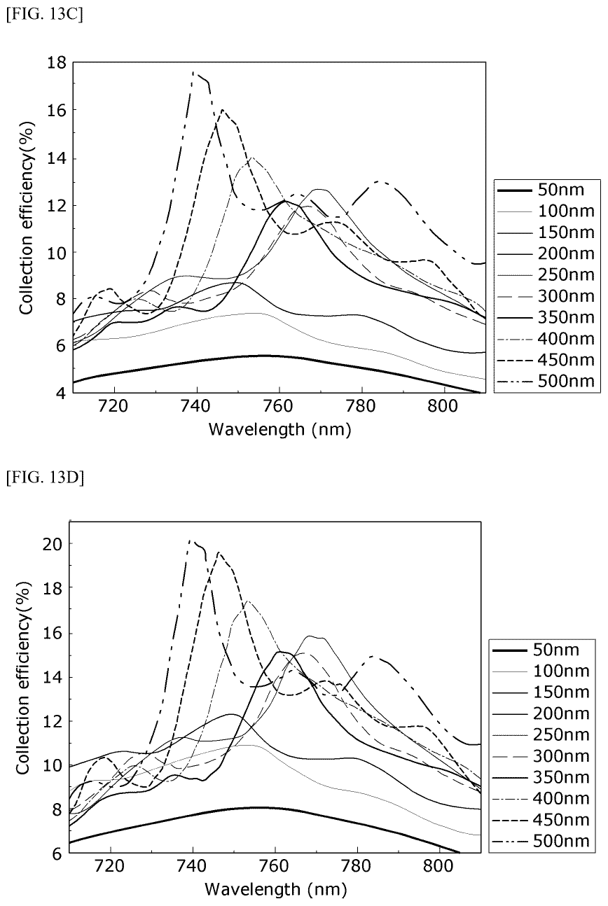

FIGS. 13A to 13D show photon collection efficiencies of the circular patterns according to wavelengths of light. FIG. 13A shows collection efficiency in the case in which an NA is 0.14 at a specified angle of 8.05°. FIG. 13B shows collection efficiency in the case in which an NA is 0.5 at a specified angle of 30°. FIG. 13C shows collection efficiency in the case in which an NA is 0.77 at a specified angle of 50°. FIG. 13D shows collection efficiency in the case in which an NA is 0.95 at a specified angle of 72°. The graphs show the cases in which etch depths are different from each other. When the angle exceeds 8.05°, the collection efficiency of a shorter wavelength tends to increase at a deeper etch depth.

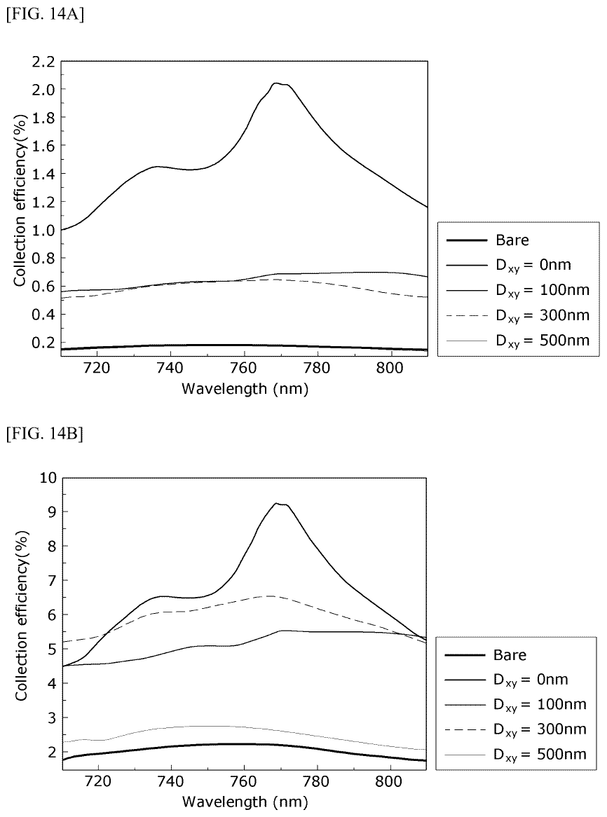

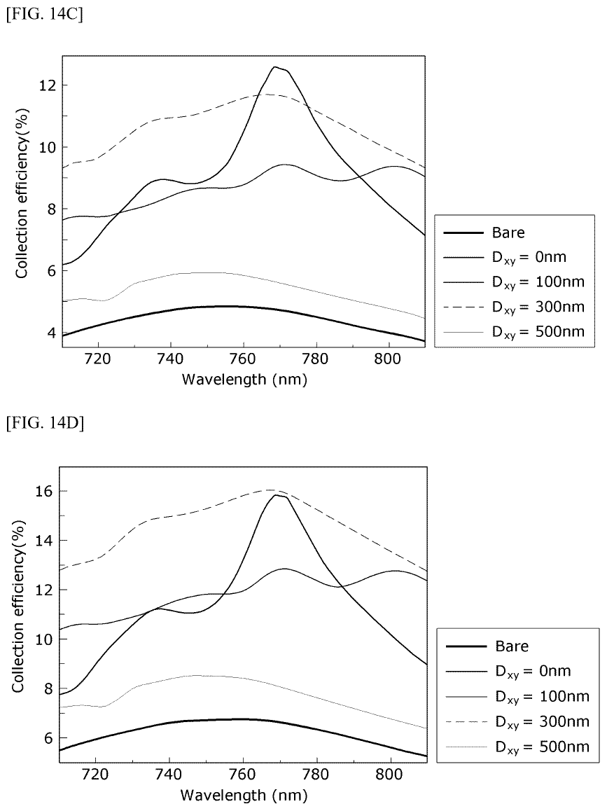

FIGS. 14A to 14D show photon collection efficiencies calculated as a single-photon emission point is changed from the center of the protruding structure to an edge of the protruding structure in the first or second direction. FIG. 14 shows the results of a computational simulation of brightness change according to the Bragg circular grating that is exactly centered on a position of the single-photon source or is at a position having some error. FIGS. 14A, 14B, 14C, and 14D show collection efficiencies at specified angles of 8.05°, 30°, 50°, and 72°, respectively. The graphs indicate the cases in which displacements are 0 nm, 100 nm, 300 nm, and 500 nm. It can be seen that, when the NA increases, the collection efficiency at the displacement of 300 nm exceeds the collection efficiency at the displacement of 0 nm. Therefore, an objective lens with a high NA may more efficiently capture a photon emitted from a single-photon source located further away from the center of the pattern.

Embodiments provide a single-photon source device having increased brightness of a single-photon source.

In addition, embodiments provide a single-photon source device with improved extraction of a single-photon.

In addition, the single-photon source device capable of continuously measuring a light emission intensity can be provided.

In addition, the single-photon source device that operates at room temperature and is miniaturized can be provided.

The single-photon source device with high precision and high stability of photon generation can be provided.

Various beneficial advantages and effects of the present invention are not limited by the detailed description and should be easily understood through a description of a detailed embodiment of the present invention.

While the present invention has been mainly described with reference to exemplary embodiments, it should be understood that the present invention is illustrative and is not limited to the embodiments, and various modifications and applications can be devised by those skilled in the art to which the present invention pertains without departing from the gist of the present invention. For example, each component specifically shown in the exemplary embodiments can be modified and implemented. It should be construed that differences related to these modifications and applications will fall within the scope of the present invention defined by the appended clams.

What is claimed is:

1. A single-photon source device comprising:
a microscope part including a stage that is three-dimensionally movable;
a wafer disposed on the stage;
a laser part configured to emit light to the wafer; and
a single-mode fiber (SMF) input/output module configured to emit an optical signal reflected by the wafer to an outside,
wherein the wafer includes a substrate and a wafer layer disposed on the substrate, and
the wafer layer has a surface on which the light is incident and which includes a plurality of circular patterns forming concentric circles.

2. The single-photon source device of claim 1, wherein the plurality of circular patterns are etched to a predetermined depth from the surface of the wafer layer, on which the light is incident, in a direction in which the light is incident.

3. The single-photon source device of claim 2, wherein the plurality of circular patterns include a first circular pattern having a first diameter and a second circular pattern having a second diameter different from the first diameter.

4. The single-photon source device of claim 3, wherein:
the first diameter is smaller than the second diameter; and
the wafer layer includes a protruding structure disposed on an inner side of the first circular pattern.

5. The single-photon source device of claim 4, wherein:
a diameter of the protruding structure is greater than a width of the first circular pattern in a first direction; and
the first direction is a direction perpendicular to the direction in which the light is incident on the wafer layer.

6. The single-photon source device of claim 3, wherein the plurality of circular patterns further include a third circular pattern to a tenth circular pattern disposed outside the second circular pattern.

7. The single-photon source device of claim 1, wherein the wafer layer is etched to 0.6 μm to 1.2 μm in a direction perpendicular to the surface on which the light is incident.

8. The single-photon source device of claim 7, wherein a surface of the etched wafer layer is spaced apart from the substrate by 0.09 μm to 0.11 μm.

9. The single-photon source device of claim 1, wherein:
the substrate includes a sapphire substrate; and
the wafer layer includes a GaN layer.

10. The single-photon source device of claim 9, wherein the plurality of circular patterns are a circular Bragg grating (CBG).

11. The single-photon source device of claim 5, wherein the diameter of the protruding structure ranges from 1500 nm to 1540 nm.

12. The single-photon source device of claim 4, wherein a difference between the first diameter and the second diameter ranges from 320 nm to 420 nm.

13. The single-photon source device of claim 3, wherein a height of each of the first circular pattern and the second circular pattern ranges from 240 nm to 260 nm.
